(19) United States
(12) Patent Application Publication
(10) Pub. No.: US 2005/0019697 A1
(43) Pub. Date: Jan. 27, 2005

(54) Method of treating wafers with photoresist to perform metrology analysis using large current e-beam systems

(75) Inventors: Daniel Tang, Fremont, CA (US); Jiong Chen, San Jose, CA (US)

Correspondence Address: Bo-In Lin, 13445 Mandoli Drive, Los Altos Hills, CA, 94022, US

(73) Assignee: Advanced Ion Beam Technology, Inc.

(21) Appl. No.: 10/626,355

(22) Filed: Jul. 24, 2003

(51) Int. Cl. G03F 7/00

(52) U.S. Cl. 430/296; 430/322; 430/324

(57) ABSTRACT

A photoresist layer is preprocessed by carrying out an ion beam implantation onto a patterned photoresist layer with conductive ions. The conductive ions may comprise ions of carbon, SB, indium, silicon, or other metallic/semiconductor atoms/molecules. The ion implantation is carried out by applying ion beams of energy lower than 1000 ev such that the pre-process implantation would not cause any alterations to the profile or layer structure of the photoresist layer. In order to assure sufficient conductivity is achieved in the photoresist layer, it is desirable that a high dose of implanting ion beam is used, preferable having a ion dosage in a range of 10¹⁶/cm² to 10¹⁸/cm². A large quantity of resist out-gassing would occur during the high dose implants. Wafers with resist patterns can thus be subject to electron beam inspections without the problems of electric charging and photoresist out-gassing.

### BACKGROUND OF THE INVENTION

1. Field of the Invention

The present invention relates generally to critical dimension (CD) and defects inspection in semiconductor manufacturing, and more particularly to a method for using scanning electron microscope (SEM) to analyze and monitor wafers with photo-resist patterns.

2. BACKGROUND

Even though a scanning electronic microscope (SEM) is commonly applied in the integrated circuit (IC) manufacturing processes to measure and monitor the surface features produced by the photolithographic processes, there are still technical difficulties that limit the applications of an e-beam system to perform high current large area photoresist defect inspections. Specifically, there are two technical difficulties encountered by those of ordinary skill in the art when applying an e-beam system for photoresist defect inspections. The first difficulty is a electron charging problem that occurs when the photoresist layer retains excessive negative charges as the electron beam are projected onto a photoresist layer and the number of emitted secondary electrons are less than the incident electrons. These negative charges retained in the photoresist layer produce an electric field that can disturb the trajectories of the incident electron beams thus degrade the scanning image and the quality of the inspections. A second difficulty is the “out-gas ” generated from the photoresist layer when an electronic beam of higher current is projected onto a photoresist layer. The gas when released from the photoresist layer into a scanning electron microscopic (SEM) chamber often causes contamination and degradation of the electron gun used in a e-beam system. Due to these reasons, even that SEM has been used for small area pattern scanning with lower e-beam current, for the purpose of photoresist defect inspection, applications of the e-beam system are still limited due to the surface charging and out-gassing problems.

With the technological advancements made in the fields of IC (integrated circuit) design and manufacturing, current ultra-large-scale integration (ULSI) micro electronic circuits requires the manufacture of electronic devices to have deep sub-micron line-width with increased density of transistors and meanwhile requiring higher speed and improved reliability. In order to satisfy these demands, it is necessary to closely watch and continuously monitor the entire manufacturing processes to accurately control and assure the quality resulting from each of these processing steps. One of the important manufacturing processes that requires careful inspection is a photolithography process, wherein masks are used to transfer circuitry patterns onto photosensitive layers, i.e., photoresist layers, which have been previously coated on semiconductor wafers. Conventionally, an optical exposure tool such as a scanner or a stepper transfers the mask patterns onto the photoresist layer. The mask directs the light or other radiation projected from a scanner or stepper through the mask to expose and imprint the patterns of the mask onto the photoresist. The photoresist is thereafter developed to form a photoresist mask. These patterns printed by photolithography will subsequently be transferred onto layer underneath through etching processes. The open areas are etched away and areas covered by the photoresist pattern will be protected and remain on the wafer. After resist patterns are successfully etched onto the underneath layer, the photoresist will be stripped away and only etched pattern layer remained on the wafer surface.

Fabrication of the mask follows a set of predetermined design rules set by processing and design limitations. These design rules define the space tolerance between devices and interconnecting lines and the width of the lines themselves, to ensure that the devices or lines do not overlap or interact with one another in undesirable ways. The design rule limitation is referred to as the critical dimension (“CD”), defined as the smallest width of a line or the smallest space between two lines permitted in the fabrication of the device. As the design rules shrink and process windows, i.e., the margins for error in processing, become smaller, inspection and measurement of surface features CD, as well as their cross-sectional shape generally referred to as the “profile ” are becoming increasingly important. Deviations of a feature's CD and profile from design dimensions may adversely affect the performance of the finished semiconductor device. Furthermore, the measurement of a feature's CD and profile may indicate processing problems, such as exposure tools defocusing or photoresist loss due to overexposure.

Using Scanning Electron Microscope (SEM) to monitor wafers with photoresist patterns has become essential because of the extremely small scale of the devices. However, even with ever increased demand, defect inspections of the photoresist layer by applying a full power CD-SEM is still not technically feasible due to the above-mentioned technical difficulties of electron charging and out-gassing.

For the purpose of overcoming the-charging problems, a ground scheme is applied by coating the surface with gold and attaching a ground wire to the coating in order to reduce charging effects. This method causes undesirable pattern structure changes. Furthermore, the gold coating cannot produce continuous and uniform layer to cover different structural features particularly those structural features that have a high aspect ratio.

As limited by the charging and out-gassing problems, current technology does employ a more limited SEM application for measuring and monitoring the surface features produced by a photo-lithographic process. Specifically, the SEM scanning processes as currently used are known as a “critical dimension scanning electron microscope ” (CD-SEM). The CD-SEM uses small electron beam current (<7 nA) and small area to minimize the charging and photoresist outgas effects. New applications have been developed recently in attempt to use the e-beam system for defect inspection. However, defect inspection with an e-beam tool would require large electron beam current (>60 nA) and large scan field to increase the sensitivity and throughput. Due the charging and out-gassing problems as discussed above, current defect inspection using e-beam system can only apply to post etched and resist stripped pattern wafers. However, the defects of the photoresist layer, if they exist, would already be transferred into the integrated circuits on the wafer. Thus, there is still a need to provide a solution to overcome these technical difficulties such that the use of an intense e-beam system to inspect a large area covered the photoresist patterns can be effectively performed.

### SUMMARY OF THE PRESENT INVENTION

It is therefore an object of this invention to provide a method that allows large area inspections of a patterned photoresist layer supported on the semiconductor wafers with intense electron beams to significantly improve the production yields such that the above-mentioned technical difficulties as encountered in the prior art can be resolved.

It is a further object of this invention to provide a method for substantially eliminating electrostatic charges to improve the accuracy of subsequent SEM-CD measurements and SEM defects inspections.

It is a further object of this invention to provide a method for substantially eliminating photo resist out gassing during SEM measurements and/or defect inspections.

Specifically, this invention discloses a method to prepress the photo resist layer by either ion-beam implanting or plasma immersing implanting a low energy high conductive ion beam onto the photoresist layer to activate a pre-inspection out-gassing and to significantly increase the conductivity of the photoresist layer. The difficulties caused by the out-gassing during the inspection can therefore be substantially resolved by first driving out the gases retained in the photoresist layer. The technical difficulties caused by the excessive electron charges are also resolved when the photoresist now has sufficient conductivity to automatically discharge excessive negative charges thus eliminating the electrostatic problems. In order to assure out-gassing from the entire photoresist layer and uniform conductivity across the entire layer are achieved, the ion-beam implanting or plasma immersing implanting processes are particularly select to apply to different structure and profile features for different types of photoresist layers such that effective large area layer inspection can be carried out.

This invention disclosed a photoresist layer preprocessing method by carrying out an ion beam implantation onto a patterned photoresist layer with conductive ions. The conductive ions may comprise ions of carbon, SB, indium, silicon, or other metallic/semiconductor atoms/molecules. The ion implantation is carried out by applying ion beams of energy lower than 1000 ev such that the pre-process implantation would not cause any alterations to the profile or layer structure of the photoresist layer. In order to assure sufficient conductivity is achieved in the photoresist layer, it is desirable that a high dose of implanting ion beam is used, preferable having a ion dosage in a range of 10¹⁶/cm² to 10¹⁸/cm². A large quantity of resist out-gassing would occur during the high dose implants. Wafers with resist patterns can thus be subject to electron beam inspections without the problems mentioned above.

To make the resist pattern surfaces electrically conductive everywhere on the resist pattern, large tilt angle implant (>30 deg) would be needed to “coat ” the sidewall of the photoresist structures. But this implantation method only can only be applied to low aspect ratio structures like poly gate patterns. For dense pattern areas and high aspect ratio structures such as contact/via holes and deep trenches, the large tilt angle implants would be shadowed and blocked by the resist patterns and becomes non-effective for side wall coating. For these types of wafers, plasma immersion implantation would be a better method that conductive ions can be uniformly coated on the sidewall. The uniformity and doping level of each method needs to be optimized.

Briefly, in a preferred embodiment, the present invention discloses a method for preprocessing a photoresist layer supported on a substrate before applying an electron inspection. The method includes a step of a) out-gassing the photoresist layer. In another preferred embodiment, the method further include a step of b) increasing a conductivity of the photoresist layer. In a preferred embodiment, the step of out-gassing and increasing the conductivity of the photoresist layer further includes a step of implanting the photoresist layer with a conductive ion.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1 is a side cross sectional view for illustrating an implantation into a photoresist layer with contact hole pattern covering a chemical vapor deposition (CVD) layer supported on a silicon substrate whereby a large area high electron beam defect inspection may be performed on the photoresist layer.

FIG. 2 is a flowchart to illustrate the processing steps for treating and prepress a photoresist layer to prepare the photoresist layer to allow for large area high electron beam defect inspection on the photoresist layer.

### DETAILED DESCRIPTION OF THE PREFERRED EMBODIMENT

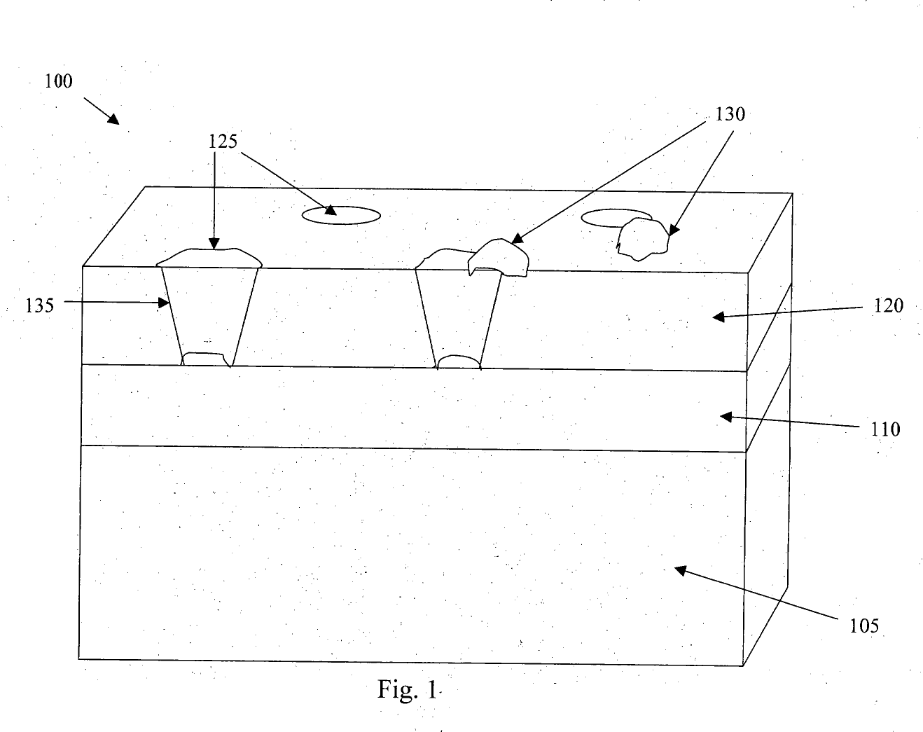

Referring to FIG. 1 for a side perspective view of a partially manufactured integrated circuit (IC) 100 supported on a silicon substrate 105. A chemical vapor deposition (CVD) layer 110 is formed on top of the substrate 105. A photoresist layer 120 formed with contact holes 125 covers the CVD layer 110. Due to the potential particles or defects 130 that may be inadvertently deposited or formed during the processes of forming the photoresist layer 120, an inspection is necessary to assure quality of IC manufacture would not be degraded as a photolithographic operation is performed with a photoresist profile 135.

In order to carry out a large current e-beam inspection of the photoresist layer 120, conductive ions 140 are implanted onto the photoresist layer 120. The ion beams of the implanting ions 140 are implanted at a low energy level, e.g., lower than 1000 ev, to prevent any damage or changes made to the resist profile. The implanting ion beams 140 must also have a high dosage to generate a high beam current so that sufficient resist out gassing occurred during implants. A high dose of implanting ion beam is used to generate the conductivity required to eliminate photoresist charging during inspection. Preferably, the dosage of the ion beams 140 would have a range between 10¹⁶/cm² to 10¹⁸/cm².

The conductive ions 140 for photoresist layer implantation can be selected to minimize the impact to the downstream processes on production wafers that may cause device impact. If the purpose of inspection is for characterizing a lithographic process, then a test wafer may be used where the impact to downstream processes on the test wafer would not be a concern. Because the test wafer may not require further processes after the inspection and there is no concern of changing the device characteristics. For practical applications, more conductive species such as In or Sb can be selected for these types of test wafers. For production monitoring, low energy carbon implants would be a preferred choice. For IC that is manufactured with advanced technology nodes, surface contamination control becomes so critical; it is preferable that a test wafer is used when this method of inspection is employed.

By applying the method disclosed in this invention, this invention further discloses a photoresist layer for integrated circuit manufacture that is processed for e-beam inspection. The photoresist layer contains an out-gas content that be significantly less than 0.5 percents thus substantially prevent out-gassing from the photoresist layer during the e-beam inspection Also this invention discloses a photoresist layer for integrated circuit manufacture processed for e-beam inspection. The photoresist layer having an resistivity less than 2000 ohm/cm² thus substantially prevent an electric charging of said photoresist layer during said e-beam inspection.

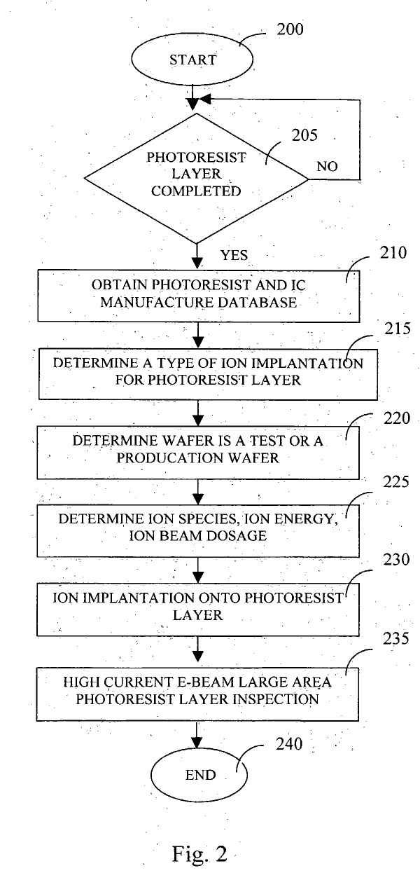

FIG. 2 is a flowchart for illustrating the processing steps of applying the method disclosed in this invention to prepare a photoresist layer such that a high current e-beam inspection can be carried out on a photoresist layer. The process starts (step 200) with a determination whether the formation of a photoresist layer is completed (step 205). When the photoresist layer is completed, a database of the profile of the photoresist layer is retrieved (step 210). Based on the profile of the photoresist layer, a determination is made for a type of ion implantation, e.g., regular ion implantation or plasma immersing implantation, should be employed depending on the aspect ratio of the photoresist layer (step 215). Then it is determined if this wafer for inspection is a production wafer or a test wafer (step 220). Based on the above information, a determination is made for the species of the ion(s) for implantation, the ion dosage, ion implant energy, and other implantation parameters (step 225) to carry out a photoresist layer implantation (230). Then, followed by conducting a high current e-beam large area photoresist inspection (step 235), the processes end (step 240).

According to above descriptions, this invention discloses a method for preparing a photoresist layer for e-beam inspection. The method includes a step of out-gassing the photoresist layer whereby an outgas from the photoresist layer during the e-beam inspection is substantially prevented. In a preferred embodiment, the step of out-gassing the photoresist layer further comprising a step of implanting ions into the photoresist layer to activate an out-gassing from the photoresist layer. In a preferred embodiment, the method further includes a step of increasing a conductivity of the photoresist layer whereby electric charging of the photoresist layer during the e-beam inspection is substantially prevented. In a preferred embodiment, the step of increasing a conductivity of the photoresist layer further includes a step of implanting conductive ions into the photoresist layer to increase a conductivity of the photoresist layer. In a preferred embodiment, the step of increasing a conductivity of the photoresist layer further includes a step of implanting carbon ions into the photoresist layer. In a preferred embodiment, the step of increasing a conductivity of the photoresist layer further includes a step of implanting indium ions into the photoresist layer. In a preferred embodiment, the step of increasing a conductivity of the photoresist layer further includes a step of implanting Sb ions into the photoresist layer. In a preferred embodiment, the step of increasing a conductivity of the photoresist layer further In a preferred embodiment, the step of increasing a conductivity of the photoresist layer further includes a step of implanting metallic ions into the photoresist layer. In a preferred embodiment, the step of increasing a conductivity of the photoresist layer further includes a step of implanting a conductive ions at an implanting energy approximately 1000 ev into the photoresist layer. In a preferred embodiment, the step of increasing a conductivity of the photoresist layer further includes a step of implanting a conductive ions having an ion dosage in a approximate range 10¹⁶/cm² to 10¹⁸/cm² into the photoresist layer. In a preferred embodiment, the step of increasing a conductivity of the photoresist layer further includes a step of plasma immersing ion implant a conductive ions into the photoresist layer. In a preferred embodiment, the method further includes a step of out-gassing the photoresist layer whereby an outgas from the photoresist layer during the e-beam inspection is substantially prevented. In a preferred embodiment, the step of out-gassing the photoresist layer further includes a step of implanting ions into the photoresist layer to activate an out-gassing from the photoresist layer.

This invention further discloses a photoresist layer for integrated circuit manufacture processed for e-beam inspection that includes an out-gas content-less than 0.5 percents thus substantially prevent out-gassing from the photoresist layer during the e-beam inspection. In a preferred embodiment, this invention further discloses a photoresist layer for integrated circuit manufacture processed for e-beam inspection that has an electric resistivity less than 2000 ohm/cm² thus substantially prevent an electric charging of the photoresist layer during the e-beam inspection. In another preferred embodiment, this invention discloses a photoresist layer for integrated circuit manufacture that includes implanted conductive ions for increasing a conductivity of the photoresist layer. In a preferred embodiment, the implanted conductive ions further include implanted carbon ions. In a preferred embodiment, the implanted conductive ions further include implanted indium ions. In a preferred embodiment, the implanted conductive ions further include implanted Sb ions. In a preferred embodiment, the implanted conductive ions further include implanted silicon ions. In a preferred embodiment, the implanted conductive ions further includes implanted metallic ions.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

1. A method for preparing a photoresist layer for e-beam inspection comprising:
out-gassing said photoresist layer whereby an outgas from said photoresist layer during said e-beam inspection is substantially prevented.

2. The method for of claim 1 wherein:
said step of out-gassing said photoresist layer further comprising a step of implanting ions into said photoresist layer to activate an out-gassing from said photoresist layer.

3. A method for preparing a photoresist layer for e-beam inspection comprising:
increasing a conductivity of said photoresist layer whereby electric charging of said photoresist layer during said e-beam inspection is substantially prevented.

4. The method for of claim 3 wherein:
said step of increasing a conductivity of said photoresist layer further comprising a step of implanting conductive ions into said photoresist layer to increase a conductivity of said photoresist layer.

5. The method for of claim 3 wherein:
said step of increasing a conductivity of said photoresist layer further comprising a step of implanting carbon ions into said photoresist layer.

6. The method for of claim 3 wherein:
said step of increasing a conductivity of said photoresist layer further comprising a step of implanting indium ions into said photoresist layer.

7. The method for of claim 3 wherein:
said step of increasing a conductivity of said photoresist layer further comprising a step of implanting Sb ions into said photoresist layer.

8. The method for of claim 3 wherein:
said step of increasing a conductivity of said photoresist layer further comprising a step of implanting silicon ions into said photoresist layer.

9. The method for of claim 3 wherein:
said step of increasing a conductivity of said photoresist layer further comprising a step of implanting metallic ions into said photoresist layer.

10. The method for of claim 3 wherein:
said step of increasing a conductivity of said photoresist layer further comprising a step of implanting a conductive ions at an implanting energy approximately 1000 ev into said photoresist layer.

11. The method for of claim 3 wherein:
said step of increasing a conductivity of said photoresist layer further comprising a step of implanting a conductive ions having an ion dosage in a approximate range 10¹⁶/cm² to 10¹⁸/cm² into said photoresist layer.

12. The method for of claim 3 wherein:
said step of increasing a conductivity of said photoresist layer further comprising a step of plasma immersing ion implant a conductive ions into said photoresist layer.

13. The method for of claim 3 further comprising:
out-gassing said photoresist layer whereby an outgas from said photoresist layer during said e-beam inspection is substantially prevented.

14. The method for of claim 13 wherein:
said step of out-gassing said photoresist layer further comprising a step of implanting ions into said photoresist layer to activate an out-gassing from said photoresist layer.

15. A photoresist layer for integrated circuit manufacture processed for e-beam inspection comprising:
an out-gas content less than 0.5 percents thus substantially prevent out-gassing from said photoresist layer during said e-beam inspection.

16. A photoresist layer for integrated circuit manufacture processed for e-beam inspection comprising:
an electric resistivity less than 2000 ohm/cm² thus substantially prevent an electric charging of said photoresist layer during said e-beam inspection.

17. A photoresist layer for integrated circuit manufacture comprising:
implanted conductive ions for increasing a conductivity of said photoresist layer.

18. The photoresist layer for of claim 17 wherein:
said implanted conductive ions further comprising implanted carbon ions.

19. The photoresist layer for of claim 17 wherein:
said implanted conductive ions further comprising implanted indium ions.

20. The photoresist layer for of claim 17 wherein:
said implanted conductive ions further comprising implanted Sb ions.

21. The photoresist layer for of claim 17 wherein:
said implanted conductive ions further comprising implanted silicon ions.

22. The photoresist layer for of claim 17 wherein:
said implanted conductive ions further comprising implanted metallic ions.
